(19) United States
(12) Patent Application Publication
(10) Pub. No.: US 2005/0153114 A1
(43) Pub. Date: Jul. 14, 2005

(54) Printing of organic electronic devices

(76) Inventors: Rahul Gupta, Milpitas, CA (US); Andrew Ingle, Fremont, CA (US); Sriram Natarajan, Burlingame, CA (US); Pierre-Marc Allemand, San Jose, CA (US)

Correspondence Address: Siemens Corporation;Attn: Elsa Keller, Legal Administrator, Intellectual Property Department, 170 Wood Avenue South, Iselin, NJ, 08830, US

(21) Appl. No.: 10/757,872

(22) Filed: Jan. 14, 2004

(51) Int. Cl. H01L 29/00; H01L 31/00; H05B 33/00

(52) U.S. Cl. 428/201; 428/195.1; 428/690; 428/917; 427/66; 427/58; 427/74; 427/258; 313/504; 313/506; 257/88; 136/263

(57) ABSTRACT

The composition of a organic (e.g. conducting polymer) solution is reformulated and the device upon which the organic solution is to be deposited is plasma treated to provide a more uniform and flat drying profile for the resulting dried film. This reformulation and treatment induces a more uniform and flatter profile when the reformulated organic solution is allowed to dry into a film on the treated device.

### BACKGROUND

1. Field of the Invention

This invention relates generally to the art of thin film device processing and fabrication. More specifically, the invention relates to the fabrication of Organic Light Emitting Diode based displays and other electronic devices which use selective deposition.

2. Related Art

Display and lighting systems based on LEDs (Light Emitting Diodes) have a variety of applications. Such display and lighting systems are designed by arranging a plurality of photoelectronic elements (“elements”) such as arrays of individual LEDs. LEDs that are based upon semiconductor technology have traditionally used inorganic materials, but recently, the organic LED (“OLED”) has come into vogue for certain applications. Examples of other elements/devices using organic materials include organic solar cells, organic transistors, organic detectors, and organic lasers. There are also a number of bio-technology applications such as biochips for DNA recognition, combinatorial synthesis, etc. which utilize organic materials.

An OLED is typically comprised of two or more thin at least partially conducting organic layers (e.g., an electrically conducting hole transporting polymer layer (HTLs) and an emissive polymer layer where the emissive polymer layer emits light) which are sandwiched between an anode and a cathode. Under an applied forward potential, the anode injects holes into the conducting polymer layer, while the cathode injects electrons into the emissive polymer layer. The injected holes and electrons each migrate toward the oppositely charged electrode and recombine to form an exciton in the emissive polymer layer. The exciton relaxes to a lower energy state by emission of radiation and in process, emits light.

Other organic electronic devices, such as organic transistors and organic sensors will also typically contain a conducting organic (polymer) layer and other organic layers. A number of these OLEDs or other organic electronic devices can be arranged in a pattern over a substrate as for instance in display system. One way of patterning organic electronic devices over a substrate is to create pockets by photolithography and then utilize a process known as ink-jet printing. The use of a photo-resist layer to define pockets for inkjet printing is disclosed in published patent application Number US2002/0060518 A1 entitled “Organic Electroluminescent Device and Method of Manufacturing Thereof”. In ink-jet printing, polymer or organic solution is deposited by discharging droplets of the solution into the pockets from a print head. One common application of inkjet printing is the patterning of multi-color OLED pixels (such as RGB patterned pixels) in order to manufacture a color display.

FIG. 1 shows a prior art ink-jet printing system used to deposit a solution. In FIG. 1, the OLED display that is being fabricated includes a substrate 109 and an anode 112 on the substrate 109. Bank structures 115 are on the anode 112; the bank structure has apertures 118 through which the anode is exposed (the apertures 118 can be pockets or lines). HTLs 121 are on the exposed portions of the anode 112. Emissive polymer layers 122 are on the HTLs 121. Here, the emissive polymer layers 122 are formed by discharging droplets 124 of a solution that includes emissive polymers onto the HTLs and then allowing this emissive polymer solution to dry. The emissive polymer solution is discharged through nozzles 127 of print-head 130. Even if the emissive polymer layers 122 would have a flat or uniform drying profile if they were directly deposited onto anode 112, the presence of the HTLs 121 will affect their profile since they are dried on top of the HTLs 121. Thus, it is important that both HTLs 121 and emissive polymer layers have a flat uniform profile. The HTLs 121 typically, under current state of the art, have very non-uniform and concave profiles as shown in FIG. 2(a).

As can be observed, the drying pattern is very non-uniform and shows a piling up on the edges of the drop 200 which represents a drop of a conducting polymer solution. This is due to the difference in the rate of evaporation at different regions of drop 200, resulting in surface tension variations which in turn causes the substance to move towards the edges of the drop 200 from the middle, and hence the ultimate deposition of more of the substance at the edge than in the middle. This phenomenon is usually referred to as the Marangoni effect. A common example of this phenomenon is the drying of a coffee stain which shows more prominence (is darker in color) on the edges of the stain than in the center.

When there are normal sloping photo-resist banks as in the case of drop 210, there is still substantial non-uniformity in the profile of the drop 210 when dried. There is accumulation at the edges which affects the useful part of the device. As the thickness of the dried film increases and becomes less uniform, the current through that part of the film decreases leading to less light being emitted from those parts. This is because in non-uniform areas of the film, the electrical characteristics do not remain very constant. This would leave less of the film that is actually usable in terms of acceptable device performance as shown.

FIG. 2(b) shows a profile and associate graph of a conventional dried conducting polymer film. There are three pockets shown, the left and right pockets with no material printed over the lower electrode layer, and a middle pocket 250 with a conducting polymer film printed over the lower electrode layer. The pocket boundaries, which are the photo-resist banks defining the pockets, are shown in the graph by the large crests. The transition between the photo-resist bank walls and the edge of the printed film in pocket 250 shows a curvature indicative of pile-up at the edges. The edges of the pocket 250 show much thicker (higher when viewed from the side)) conducting polymer film than in the center. As shown, there is substantial non-uniformity across the width of the pocket 250. The darker striations represent areas where the conducting polymer film is thicker and the lighter striations areas where the film is thinner. This corresponds roughly with the picture illustrated in FIG. 2(a) where there is pile-up of conducting polymer film at the edges.

It would be desirable to fabricate conducting polymer films that are more uniform in thickness and thus have a flatter profile than is typically observed.

### SUMMARY

In accordance with the invention, the composition of a organic (e.g. conducting polymer) solution is reformulated and the device is treated with a plasma process prior to deposition of the reformulated solution. This reformulation and device treatment induces a more uniform and flatter profile when the reformulated organic solution is allowed to dry into a film on a selected surface of the device.

In the case of an OLED, the reformulation of conducting polymer solution involves mixing a base conducting polymer solution with humectants and water. The humectants help to increase the drying time of the solution by decreasing the evaporation rate oh the ink while the water serves to lower the solids content of the reformulated conducting polymer solution. In addition, the OLED is treated with a fluorinating plasma. This device treatment modifies the surface energy of the deposition surface in relation to the surface energy of the photo-resist banks which define the surrounding pocket. The use of the reformulated conducting polymer solution and application of a device treatment yields a substantially uniform and flat profile of dried film resulting from deposition of that solution on the device.

### BRIEF DESCRIPTION OF THE DRAWINGS

FIG. 1 illustrates an example of a inkjet printing system for fabricating patterned surfaces.

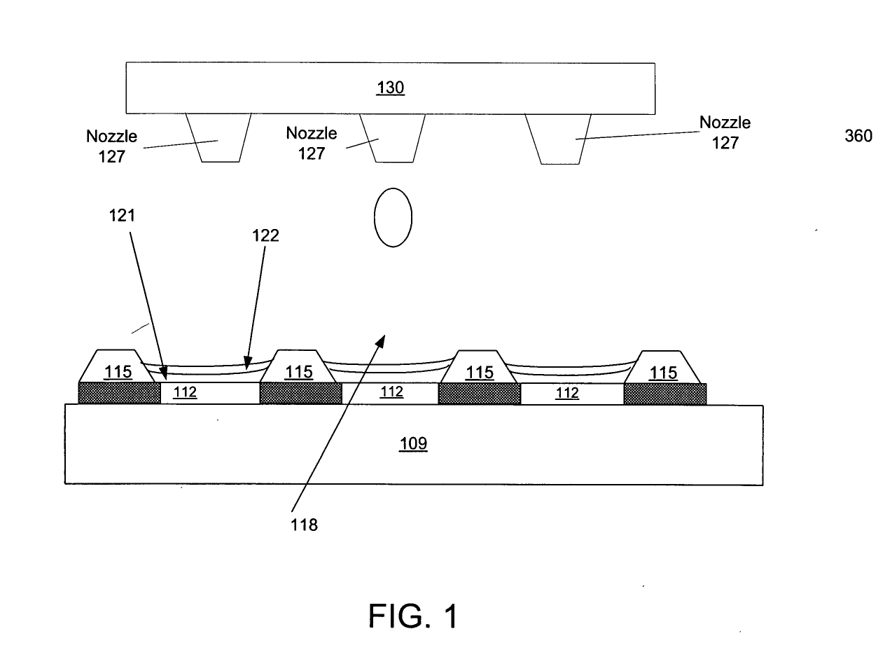

FIG. 2(a) illustrates the drying pattern of a liquid substance when the substance is dropped with and without banks.

FIG. 2(b) shows a profile and associate graph of a conventional dried conducting polymer film.

FIG. 3 illustrates the drying profile of a substance dropped into photo-resist banks in accordance with the invention.

FIG. 4 illustrates a cross-section of the layers of an OLED device in accordance with the invention.

FIG. 5 shows a workflow of fabricating an OLED in accordance with the invention.

FIG. 6 illustrates the drying profile of a reformulated conducting polymer solution dried into film in accordance with the invention.

### DETAILED DESCRIPTION OF THE INVENTION

In accordance with the invention, the composition of an organic (e.g. conducting polymer) solution is reformulated and the device, upon which the reformulated solution is to be deposited, is treated prior to deposition. This reformulation and device treatment induces a more uniform and flatter profile when the reformulated organic solution is allowed to dry into a film on a surface of the treated device.

In the case of an OLED, the organic solution is a conducting polymer solution. The reformulation of conducting polymer solution involves mixing a base conducting polymer solution with humectants and water. The humectants help to increase the drying time of the solution by decreasing the evaporation rate of the ink while the water serves to lower the solids content of the reformulated conducting polymer solution. In addition, the OLED upon which the reformulated conducting polymer solution is to be deposited is treated with a fluorinating plasma. This treatment modifies the surface energy of the deposition surface in relation to the surface energy of the photo-resist banks which define the surrounding pocket. The use of the reformulated conducting polymer solution and device treatment yields a substantially uniform and flat profile of dried film resulting from deposition of that solution on a surface of the treated device.

In other embodiments of the invention, a process of fabricating an organic electronic device is disclosed whereby 1) an organic solution is reformulated with humectants and water and 2) prior to deposition of the organic solution, the entire device being fabricated is treated with a fluorinating plasma such that certain surfaces are selectively made more hydrophobic and other surfaces are made more hydrophilic. In the case of an OLED, the exposed deposition surface (usually the lower electrode layer) is made more hydrophilic and photo-resist banks are made more hydrophobic. The organic solution is then deposited and allowed to evaporate and dry into a layer of film which has a substantially flat and uniform profile. After the deposition of conducting polymer, other steps are carried out to complete the organic electronic device fabrication. Examples of such fabricated organic electronic devices include OLEDs, organic transistors, organic solar cells and so on.

In one embodiment of the invention, the ratio of base organic (conducting polymer) solution to humectants to water was found to be approximately 30:40:30, respectively. The surface treatment in such an embodiment should be sufficient such that the surface energy of the deposition surface is very high compared to the surface energy of the surrounding pocket-defining photo-resist walls. In other words, the deposition surface is made more hydrophilic while the photo-resist walls are made more hydrophobic.

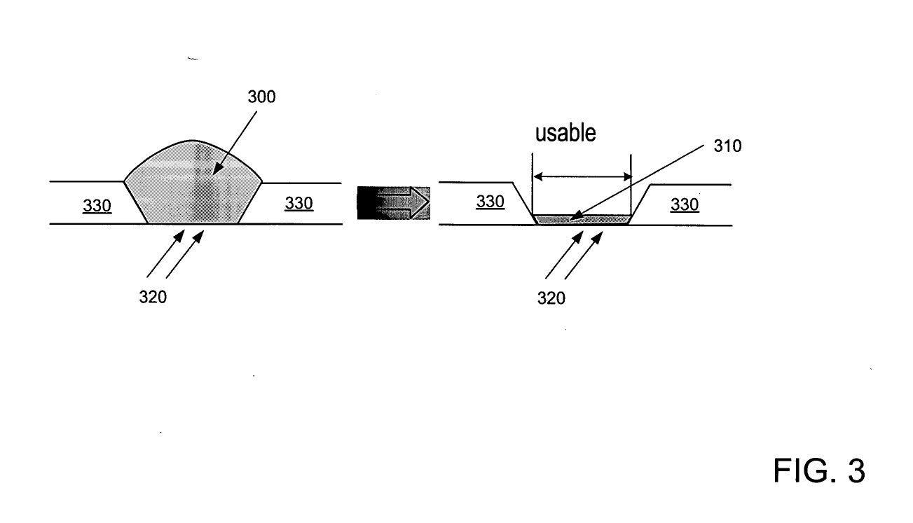

FIG. 3 illustrates the drying profile of a reformulated organic solution deposited onto a treated surface 320 surrounded by photo-resist banks. In accordance with the invention, the reformulated organic solution 300 contains a base organic solution (such as a conducting polymer) which is mixed with humectants and water. The humectants increase the drying time of the reformulated solution by decreasing the evaporation rate of the solution. The water (as well as the humectants) in the reformulated organic solution 300 help to reduce the solids content of the solution. Also, in accordance with the invention, deposition surface 320 is the surface of a lower layer (such as electrode layer) of the device which has been treated prior to deposition of the solution 300. The treatment consists of a plasma process whereby the device is fluorinated via plasma generated with both oxygen and sulfur hexafluoride. This treatment of the device will affect both the photo-resist banks 330 (which forms the pockets for solution deposition) and the deposition surface 320. This treatment causes the surface energy of the deposition surface 320 to be much greater than the surface energy of the photo-resist banks 330. After plasma treatment and reformulation, reformulated solution 300 is deposited onto surface 320. The reformulated organic solution 300 dries between the photo-resist banks 330 into film 310 over treated surface 320.

The plasma treatment, when applied to the device, creates a differential in surface energies between the photo-resist banks 330 and the treated surface 320 that prevents the liquid from flowing to bank walls and thus, there is less pile-up or build up of the drying substance at the edges. In addition, the reformulation of the organic solution helps to ensure that the drying becomes uniform. The overall effect that has been observed in experiments is a flattening the drying profile making the thickness of the dried organic film 310 more uniform thus increasing the useful area of the film 310. The drop 300 is assumed in this example to have spread or be of sufficient volume to contact the walls of the photo-resist banks 330 as shown. Drop 300 may be a single drop or series of individual drops that have coalesced together into one mass, depending on the volume of liquid, printing technology employed and so on.

In one embodiment of the invention where the device being manufactured is an OLED, the base organic solution is a conductive polymer solution which can formed from, for example, polyethylenedioxythiophene (“PEDOT”) and polystyrenesulfonic acid (“PSS”) (hereinafter “PEDOT:PSS solution”). In typical OLED devices, the PEDOT:PSS solution has a ratio of PEDOT to PSS which is one part to six parts, respectively. For an OLED device manufactured in accordance with at least one embodiment of the invention, the ratio of PEDOT to PSS in the base (before reformulation) PEDOT:PSS solution should be about one part to six parts, respectively. In accordance with the invention, this base 1:6 PEDOT:PSS solution is reformulated by adding humectants and water. In some embodiments of the invention, the reformulated conducting polymer solution should have a ratio of base 1:6 PEDOT:PSS solution to humectants to water of 30 parts to 40 parts to 30 parts, respectively. For a bottom emitting OLED device, the treated surface 320 would be the surface of an anode layer such as that composed of ITO (Indium Tin-Oxide). Examples of humectants, PEDOT:PSS and other organic solutions and surface treatments are discussed below.

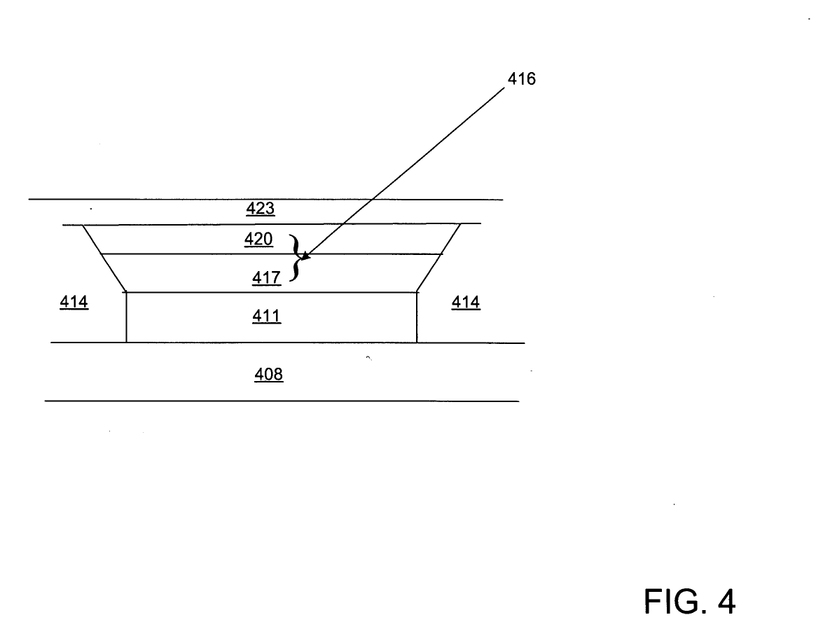

FIG. 4 shows a cross-sectional view of an embodiment of an organic electronic device 405 according to the invention. As shown in FIG. 4, the organic electronic device 405 includes a first electrode 411 on a substrate 408. As used within the specification and the claims, the term “on” includes when layers are in physical contact and when layers are separated by one or more intervening layers. The first electrode 411 may be patterned for pixilated applications or unpatterned for backlight applications. If the electronic device 405 is a transistor, then the first electrode may be, for example, the source and drain contacts of that transistor. A photo-resist material is deposited on the first electrode 411 and patterned to form a bank structure 414 having an aperture that exposes the first electrode 411. The aperture may be a pocket (e.g., a pixel of an OLED display) or a line. The bank structure 414 is an insulating structure that electrically isolates one pocket from another pocket or one line from another line.

One or more organic materials is deposited into the aperture to form one or more organic layers of an organic stack 416. The organic stack 416 is on the first electrode 411. The organic stack 416 includes a hole transporting (conducting polymer) layer (“HTL”) 417 and other active organic layer 420. If the first electrode 411 is an anode, then the HTL 417 is on the first electrode 411. Alternatively, if the first electrode 411 is a cathode, then the active electronic layer 420 is on the first electrode 411, and the HTL 417 is on the active electronic layer 420. The electronic device 405 also includes a second electrode 423 on the organic stack 416. If the electronic device 405 is a transistor, then the second electrode 423 may be, for example, the gate contact of that transistor. Other layers than that shown in FIG. 4 may also be added including insulating layers between the first electrode 411 and the organic stack 416, and/or between the organic stack 416 and the second electrode 423 and/or between active electronic layer 420 and HTL 417). Some of these layers, in accordance with the invention, are described in greater detail below.

Substrate 408:

The substrate 408 can be any material that can support the organic and metallic layers on it. The substrate 408 can be transparent or opaque (e.g., the opaque substrate is used in top-emitting devices). By modifying or filtering the wavelength of light which can pass through the substrate 408, the color of light emitted by the device can be changed. The substrate 408 can be comprised of glass, quartz, silicon, plastic, or stainless steel; preferably, the substrate 408 is comprised of thin, flexible glass. The preferred thickness of the substrate 408 depends on the material used and on the application of the device. The substrate 408 can be in the form of a sheet or continuous film. The continuous film can be used, for example, for roll-to-roll manufacturing processes which are particularly suited for plastic, metal, and metallized plastic foils. The substrate can also have transistors or other switching elements built in to control the operation of the device.

First Electrode 411:

In one configuration, the first electrode 411 functions as an anode (the anode is a conductive layer which serves as a hole-injecting layer and which comprises a material with work function greater than about 4.5 eV). Typical anode materials include metals (such as platinum, gold, palladium, indium, and the like); metal oxides (such as lead oxide, tin oxide, ITO, and the like); graphite; doped inorganic semiconductors (such as silicon, germanium, gallium arsenide, and the like); and doped conducting polymers (such as polyaniline, polypyrrole, polythiophene, and the like).

The first electrode 411 can be transparent, semi-transparent, or opaque to the wavelength of light generated within the device. The thickness of the first electrode 411 is from about 10 nm to about 1000 nm, preferably, from about 50 nm to about 200 nm, and more preferably, is about 100 nm. The first electrode layer 411 can typically be fabricated using any of the techniques known in the art for deposition of thin films, including, for example, vacuum evaporation, sputtering, electron beam deposition, or chemical vapor deposition.

In accordance with the invention, the top exposed surface of first electrode 411 would be treated a fluorinating plasma. The fluorinating plasma can be carbon tetrafluoride (CF₄) or sulfur hexafluoride (SF₆). The fluorinating plasma treatment will raise the surface energy of the surface of top electrode 411.

In an alternative configuration, the first electrode layer 411 functions as a cathode (the cathode is a conductive layer which serves as an electron-injecting layer and which comprises a material with a low work function). The cathode, rather than the anode, is deposited on the substrate 408 in the case of, for example, a top-emitting OLED. Typical cathode materials are listed below in the section for the “second electrode 423”.

Bank Structure 414:

The bank structure 414 is made of a photo-resist material such as, for example, polyimides or polysiloxanes. The photo-resist material can be either positive photo-resist material or negative photo-resist material. The bank structure 414 is an insulating structure that electrically isolates one pocket from another pocket or one line from another line. The bank structure 414 has an aperture that exposes the first electrode 411. The aperture may represent a pocket or a line. The bank structure 414 is patterned by applying lithography techniques to the photo-resist material, or by using screen printing or flexo-printing to deposit the bank material in the desired pattern. As shown in FIG. 4, the bank structure 414 can have, for example, a trapezoidal configuration in which the angle between the side wall of the bank structure 414 and the first electrode 411 is an obtuse angle. The banks may also be any other suitable shape such as curved or semi-circular. In accordance with the invention, the surface treatment of the surface of first electrode 411 causes the surface energy of the surface of first electrode 411 to be much greater than the surface energy of the side walls of the bank structure 414.

HTL 417:

The HTL 417 has a much higher hole mobility than electron mobility and is used to effectively transport holes from the first electrode 411 to the substantially uniform organic polymer layer 420. The HTL 417 is made of polymers or small molecule materials. For example, the HTL 417 can be made of tertiary amine or carbazole derivatives both in their small molecule or their polymer form, conducting polyaniline (“PANI”), or PEDOT:PSS. The HTL 417 has a thickness from about 5 nm to about 1000 nm, preferably from about 20 nm to about 500 nm, and more preferably from about 50 to about 250 nm.

The HTL 417 functions as: (1) a buffer to provide a good bond to the substrate; and/or (2) a hole injection layer to promote hole injection; and /or (3) a hole transport layer to promote hole transport.

The HTL 417 can be deposited using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating. The hole transporting material is deposited on the first electrode 411 and then allowed to dry into a film. The dried material represents the hole transport layer.

As mentioned above, in accordance with the invention, the first electrode layer 411 is treated with a fluorinating plasma prior to any deposition of the organic material used to form HTL 417. In addition, the organic material such as PEDOT:PSS solution, is first reformulated prior to deposition. The reformulation consists of adding humectants and water to the base PEDOT:PSS solution. One example of a typical PEDOT:PSS solution is Baytron P CH8000 which has a PEDOT to PSS ratio of one part to twenty parts. However, preferred embodiments of the invention use base PEDOT:PSS solutions that have a lower PEDOT to PSS ratio, such as one part PEDOT for every six parts PSS. In a preferred embodiment, Baytron AI4083 is used as the base PEDOT:PSS solution which is then reformulated. In experimental studies, reformulation was to result in a ratio of AI4083 to humectants to water of 30 parts to 40 parts to 30 parts, respectively. A reformulation of AI4083 with water and humectants as well as surface treatment of first electrode 411, yields a dried HTL 417 which is more uniform and flat in profile than non-reformulated solutions on non-treated electrode surfaces. The use of Baytron AI4083, which is manufactured by H. C. Starck, a division of Bayer AG, is merely exemplary however. Examples of humectants include propanediol, most glycols (such as ethylene glycol), glycerols, and ethers, and derivatives, families, or combinations thereof.

The invention can serve to provide a flat and uniform drying profile of any PEDOT:PSS solution or any organic solution through a process of reformulation and treating of the surface on which the solution is to be dried. Further, the ratio of humectants, water and solution, as well as the PEDOT:PSS ratio (if any) may be different than the examples given above, and can be readily determined experimentally or by other means. The invention is not thus limited to any one type of solution or reformulation. Other reformulation may exclude water or humectants or both and substitute other ingredients therefore.

Active Electronic Layer 420:

Active electronic layer 420 can include one or more layers. Active electronic layer 420 includes an active electronic material. Active electronic materials can include a single active electronic material, a combination of active electronic materials, or multiple layers of single or combined active electronic materials. Preferably, at least one active electronic material is organic.

For organic LEDs (OLEDs), the active electronic layer 316 contains at least one organic material that emits light. These organic light emitting materials generally fall into two categories. The first category of OLEDs, referred to as polymeric light emitting diodes, or PLEDS, utilize polymers as part of active electronic layer 420. The polymers may be organic or organometallic in nature. As used herein, the term organic also includes organometallic materials. Preferably, these polymers are solvated in an organic solvent, such as toluene or xylene, and spun (spin-coated) onto the device, although other deposition methods are possible. Devices utilizing polymeric active electronic materials in active electronic layer 316 are especially preferred. In addition to materials that emit light, active electronic layer 420 may include a light responsive material that changes its electrical properties in response to the absorption of light. Light responsive materials are often used in detectors and solar panels that convert light energy to electrical energy.

If the organic electronic device is an OLED or an organic laser, then the organic polymers are electroluminescent (“EL”) polymers that emit light. The light emitting organic polymers can be, for example, EL polymers having a conjugated repeating unit, in particular EL polymers in which neighboring repeating units are bonded in a conjugated manner, such as polythiophenes, polyphenylenes, polythiophenevinylenes, or poly-p-phenylenevinylenes or their families, copolymers, derivatives, or mixtures thereof. More specifically, the organic polymers can be, for example: polyfluorenes; poly-p-phenylenevinylenes that emit white, red, blue, yellow, or green light and are 2-, or 2, 5-substituted poly-p-pheneylenevinylenes; polyspiro polymers; LUMATION polymers that emit green, red, blue, or white light and are produced by Dow Chemical, Midland Michigan; or their families, copolymers, derivatives, or mixtures thereof.

If the organic electronic device is an organic solar cell or an organic light detector, then the organic polymers are light responsive material that changes its electrical properties in response to the absorption of light. The light responsive material converts light energy to electrical energy.

If the organic electronic device is an organic transistor, then the organic polymers can be, for example, polymeric and/or oligomeric semiconductors. The polymeric semiconductor can comprise, for example, polythiophene, poly(3-alkyl)thiophene, polythienylenevinylene, poly(para-phenylenevinylene), or polyfluorenes or their families, copolymers, derivatives, or mixtures thereof.

In addition to polymers, smaller organic molecules that emit by fluorescence or by phosphorescence can serve as a light emitting material residing in active electronic layer 316. Unlike polymeric materials that are applied as solutions or suspensions, small-molecule light emitting materials are preferably deposited through evaporative, sublimation, or organic vapor phase deposition methods. Combinations of PLED materials and smaller organic molecules can also serve as active electronic layer. For example, a PLED may be chemically derivatized with a small organic molecule or simply mixed with a small organic molecule to form active electronic layer 316.

In addition to active electronic materials that emit light, active electronic layer 420 can include a material capable of charge transport. Charge transport materials include polymers or small molecules that can transport charge carriers. For example, organic materials such as polythiophene, derivatized polythiophene, oligomeric polythiophene, derivatized oligomeric polythiophene, pentacene, compositions including C60, and compositions including derivatized C60 may be used. Active electronic layer 420 may also include semiconductors, such as silicon or gallium arsenide.

Second Electrode (423)

In one embodiment, second electrode 423 functions as a cathode when an electric potential is applied across the first electrode 411 and second electrode 423. In this embodiment, when an electric potential is applied across the first electrode 411, which serves as the anode, and second electrode 423, which serves as the cathode, photons are released from active electronic layer 420 that pass through first electrode 411 and substrate 408.

While many materials, which can function as a cathode, are known to those of skill in the art, most preferably a composition that includes aluminum, indium, silver, gold, magnesium, calcium, and barium, or combinations thereof, or alloys thereof, is utilized. Aluminum, aluminum alloys, and combinations of magnesium and silver or their alloys are especially preferred.

Preferably, the thickness of second electrode 423 is from about 10 to about 1000 nanometers (nm), more preferably from about 50 to about 500 nm, and most preferably from about 100 to about 300 nm. While many methods are known to those of ordinary skill in the art by which the first electrode material may be deposited, vacuum deposition methods, such as physical vapor deposition (PVD) are preferred. Other layers (not shown) such as a barrier layer and getter layer may also be used to protect the electronic device. Such layers are well-known in the art and are not specifically discussed herein.

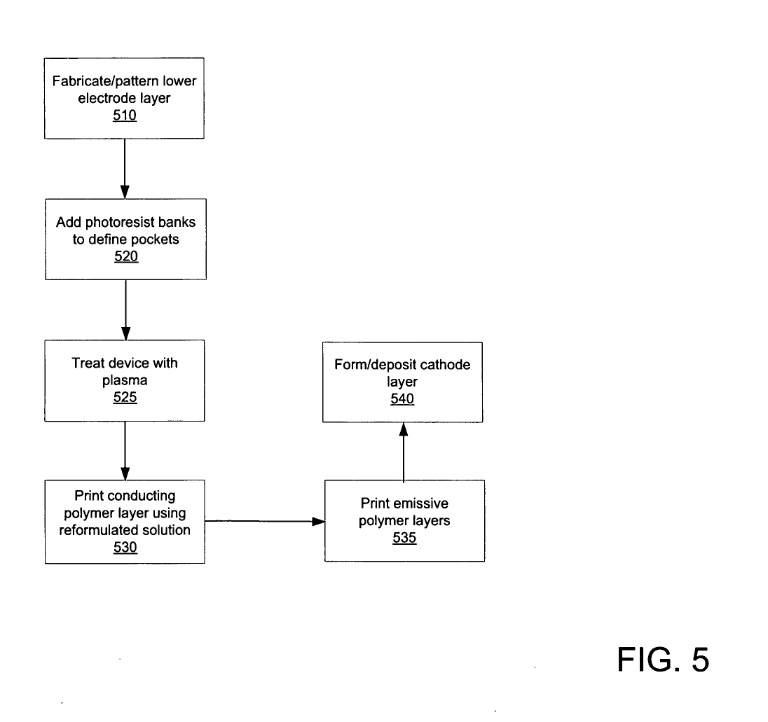

FIG. 5 shows a workflow of fabricating an organic electronic device in accordance with the invention. First, a lower electrode layer is fabricated/patterned over a substrate (step 510). The lower electrode layer preferably functions as an anode in the case of an OLED device. Typical anode materials include metals (e.g. aluminum, silver, copper, indium, tungsten, lead etc.); metal oxides; graphite; doped inorganic semiconductors (such as doped silicon, gallium arsenide and the like); and doped conducting polymers (such as polyaniline, polythiopene and the like). For OLEDs, the lower electrode layer is usually thin enough so as to be semi-transparent and allow at least a fraction of light to transmit through (in bottom emitting OLEDs). As such, any thin-film deposition method may be used in the fabricating step 510. These include, but are not limited to, vacuum evaporation, sputtering, electron beam deposition, chemical vapor deposition, etching and other techniques known in the art and combinations thereof. The process also usually involves a baking or annealing step in a controlled atmosphere to optimize the conductivity and optical transmission of anode layer. Photolithography can then be used to define any pattern in the lower electrode layer.

The next step is to add photo-resist banks such that pockets in the anode layer are defined (step 520). The photo-resist banks are fabricated by applying lithography techniques to a photo-resist material (or by using screen printing or flexo-graphic printing to deposit the bank material in the desired pattern). Photo-resist material is usually classified in two types, either positive or negative. Positive photo-resist is photo-resist which dissolves wherever exposed to light. Negative photo-resist is photo-resist which dissolves everywhere except where exposed to light. Using light radiation and techniques such as chemical developing, the photo-resist can be patterned into the desired bank shape. Examples of positive resists are those materials comprised of polyimides and so on. Either positive or negative photo-resist can be used as desired in forming the banks. Photo-resist chemistry and processes such as lithography, baking, developing, etching and radiation exposure which can be used in patterning the photo-resist into banks are known to those skilled in the art.

Next, the entire device is treated by a plasma process (step 525). Specifically, in at least one embodiment, the substrate which is now patterned with both the electrode layer and the photo-resist layers is exposed to a fluorinating plasma comprised of CF4, SF6 and oxygen. The plasma treatment selectively raises the surface energy of the electrode surface and lowers the surface energy of the photo-resist banks.

Next, the conducting polymer layer is printed using a reformulated solution (step 530). The conducting polymer layer is also referred to as a hole transport layer (“HTL”). The conducting polymer layer is used to improve, for example, the charge balance, the display stability, the turn-on voltage, the display brightness, the display efficiency, and the display lifetime. The conducting polymer layer is used to enhance the hole yield of the OLED relative to the potential applied across it and thus, aids in more energy-efficient injection of holes into the emissive polymer layer for recombination. The reformulated conducting polymer (HTL) has a surface energy/surface tension is higher than the treated banks and lower than the treated electrode and thus spreads on the higher surface energy electrode while not coating the lower surface energy banks resulting in a flat uniform film upon drying.

In accordance with the invention, a base conducting polymer solution is reformulated at some point prior to being printed in the pocket and over the lower electrode layer in step 530. This reformulation involves mixing a base conducting polymer solution with humectants and water in specified ratios. The humectants will control the rate of drying while the water will reduce the solids content of the reformulated solution. Examples of reformulated conducting polymer solutions are described above, including exemplary ratios of humectants and water.

In accordance with the invention, however, the conducting polymer layer is preferably applied using printing techniques such as ink-jet printing (screen printing, flexo-graphic printing). Particularly, in this instance, the conducting polymer layer is printed onto the lower electrode layer within pockets defined by photo-resist banks. The conducting polymer layer is printed by depositing the reformulated liquid solution containing the conducting polymer (and water and humectants) into the pocket and allowing the substance to dry. The dried film then represents the conducting polymer layer. The reformulation of the base conducting polymer solution and the plasma treatment of the device enable the conducting polymer layer to have a uniformly flat profile after drying is complete. The conducting polymer layer can also be applied using techniques such as spin coating, dip coating, roll coating, spray coating or thermal evaporation.

Then according to step 535, the emissive polymer layers are printed. The emissive polymer layer is primarily responsible for the emission of light from the OLED and is thus a electroluminescent, semi-conducting and organic (organo-metallic) type material as discussed above. In inkjet printing, there may be a plurality of different emissive polymer substances. For instance, there may be red, green and blue emitting emissive polymers in the print head which are deposited depending upon the desired color to be emitted in a given pixel location which is defined by a pocket. The emitting polymer substances are deposited on the conducting polymer layer by the print head in the exact area defined by the pockets. The emissive polymer layer results from the drying of the substance deposited by the print head.

Both the conducting polymer layers and emissive polymer layers can be printed by depositing a liquid solution in between the photo-resist banks which define a pocket. This liquid solution may be any “fluid” or deformable mass capable of flowing under pressure and may include solutions, inks, pastes, emulsions, dispersions and so on. The liquid may also contain or be supplemented by further substances which affect the viscosity, contact angle, thickening, affinity, drying, dilution and so on of the deposited drops. In at least one embodiment of the invention, the ideal viscosity of the reformulated conducting polymer solution is in the range of 10-20 Centipoise. The viscosity range is merely exemplary and can be modified higher based on the allowances provided by improved/different inkjet printing technology. In at least one embodiment of the invention, the surface tension of the reformulated conducting polymer solution should be in the range of 40-60 dyne/cm.

After the emissive polymer layer is printed, the upper electrode layer is formed/deposited (step 540). In OLED devices, the upper electrode layer functions as a cathode (if the lower electrode layer is the anode). Cathode layer materials are discussed above. Insulating materials such as LiF, NaF, CsF and so on may also be used below the upper electrode layer to enhance injection by tunneling. The lower electrode layer is formed/deposited typically using vacuum evaporation or similar techniques and often using specially designed deposition devices. Often other steps such as the addition of masks and photo-resists may precede the cathode deposition step 540. However, these are not specifically enumerated as they do not relate specifically to the novel aspects of the invention. Other steps (not shown) like adding metal lines to connect the anode lines to power sources may also be included in the workflow. The workflow of FIG. 5 is not intended to be all-inclusive and is merely exemplary. For instance, after the OLED is fabricated it is often encapsulated to protect the layers from environmental damage or exposure. Such other processing steps are well-known in the art and are not a subject of the invention.

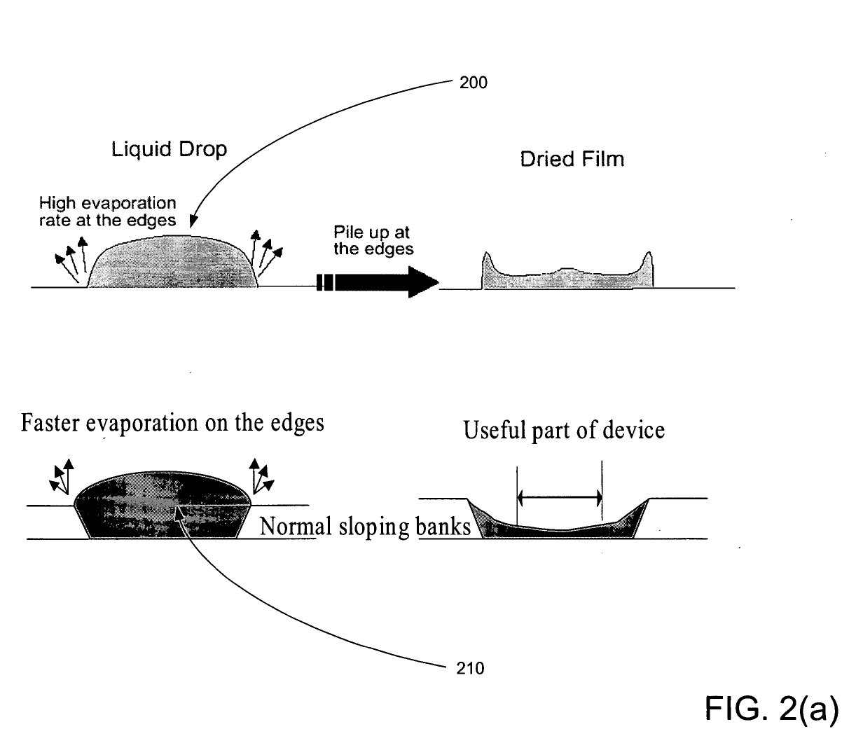

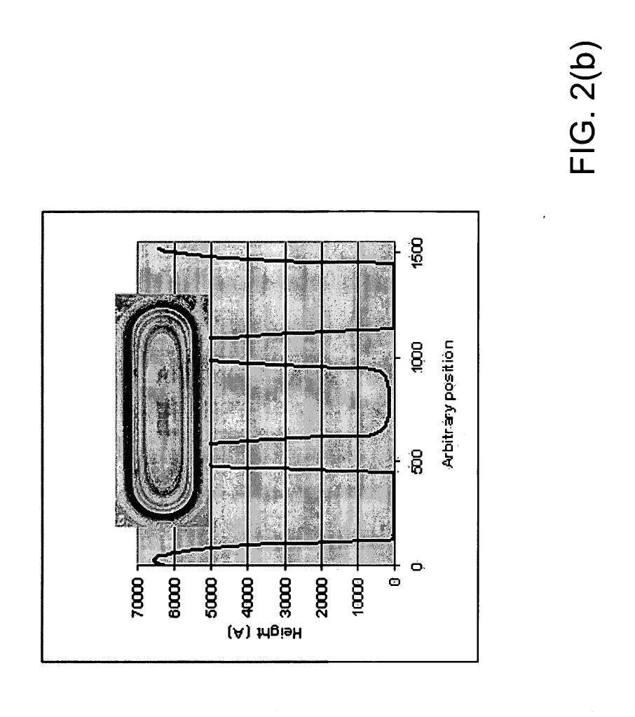

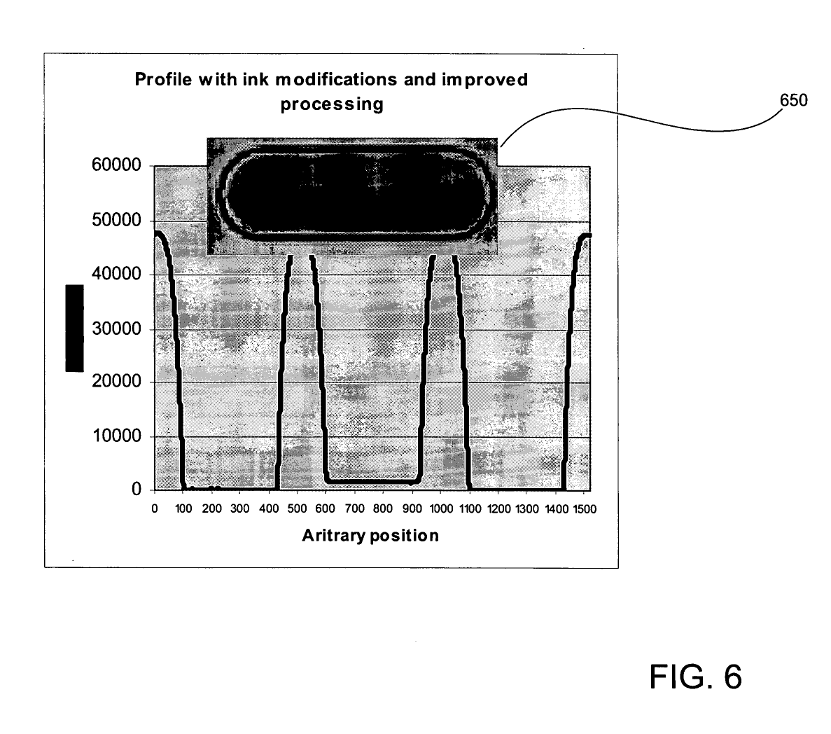

FIG. 6 illustrates the drying profile of a reformulated conducting polymer solution dried into film in accordance with the invention. As shown, there is substantial uniformity across the width of the pocket 650. Most areas of the pocket 650 have similar film thickness as illustrated by the uniform level of shading across the pocket 650. This indicates a roughly flat profile without great variations, in stark contrast to the profile illustrated in FIG. 2(b). The graph represents a profilometry trace across three pockets. The reference surfaces are unprinted ITO (lower electrode) layers which are exhibited on the profilometry trace at between roughly 100 to 400 nanometers and roughly 1100 to 1400 nanometers. The sharp rise between roughly 425 and 600 nanometers and between 900 and 1100 nanometers represents the photo-resist banks that define the pockets in between. The area between 600 and 900 nanometers represents the printed film resulting from printing a reformulated conducting polymer solution (CH8000 in this case) on a treated surface in accordance with the invention. The sharp edge transition at about 600 nanometers represents the boundary of the printed film against the wall of the photo-resist bank. This demonstrates that there is much less pile-up near the walls of the photo-resist bank (at the edge of the printed film) than conventional printed film as shown in FIG. 2(b). The area between 600 and 900 nanometers is bounded by a virtually flat line which shows that the height of the film across its width is very uniform. Compared to the curved area for the printed film in FIG. 2(b), this demonstrates a substantially more uniform profile for the printed film when the invention is employed.

The invention can serve to provide a flat and uniform drying profile of any PEDOT:PSS solution or any organic solution through a process of reformulation and treating of the surface on which the solution is to be dried. Further, the ratio of humectants, water and solution, as well as the PEDOT:PSS ratio (if any) may be different than the examples given above, and can be readily determined experimentally or by other means. The invention is not thus limited to any one type of solution or reformulation. Other reformulation may exclude water or humectants or both and substitute other ingredients therefore.

While the embodiments of the invention are illustrated in which it is primarily incorporated within an OLED display, almost any type of electronic device that uses dried film layers may be potential applications for these embodiments. In particular, present invention may also be utilized in a solar cell, a transistor, a phototransistor, a laser, a photo-detector, or an opto-coupler. It can also be used in biological applications such as bio-sensors or chemical applications such as applications in combinatorial synthesis etc. The OLED display described earlier can be used within displays in applications such as, for example, computer displays, information displays in vehicles, television monitors, telephones, printers, and illuminated signs.

1. An organic electronic device, comprising:
a deposition surface;
a photo-resist layer, said photo-resist layer fabricated upon said deposition surface, said photo-resist layer patterned into a plurality of banks to define pockets upon said deposition surface; and
an organic layer, said organic layer composed of a dried film resulting from drying a reformulated organic solution upon said deposition surface and within said pockets, said reformulated organic solution comprised of a mixture of base organic solution and humectants, further wherein the surface energy of said deposition surface is much lower than the surface energy of said photo-resist layer banks, said dried film having a substantially flat and uniform profile.

2. A device according to claim 1 wherein said organic layer is a conducting polymer layer.

3. A device according to claim 2 wherein said reformulated organic solution includes a base conducting polymer solution, humectants and water.

4. A device according to claim 1 wherein said device is treated with a plasma process to selectively cause said deposition surface to be more hydrophilic and said photo-resist banks to be more hydrophobic.

5. A device according to claim 2 wherein said organic electronic device is a OLED device.

6. A device according to claim 5 wherein said deposition surface is the lower electrode layer.

7. A device according to claim 6 further comprising an emissive layer, said emissive layer fabricated over said conducting polymer layer, said emissive layer emitting light upon charge recombination.

8. A device according to claim 7 further comprising a cathode layer disposed over said emissive layer.

9. A device according to claim 3 wherein said base conducting polymer solution is a PEDOT:PSS solution.

10. A device according to claim 9 wherein the ratio of PEDOT to PSS is one part to six parts, respectively.

11. A device according to claim 10 wherein the ratio of base conducting polymer solution to humectants to water is thirty parts to forty parts to thirty parts, respectively.

12. A device according to claim 1 wherein said device is an organic transistor.

13. A device according to claim 1 wherein said device is an organic solar cell.

14. A method of fabricating an organic electronic device, said method comprising:
patterning a lower electrode layer upon a substrate, said lower electrode layer having a top exposed deposition surface;
fabricating a photo-resist layer upon said lower electrode layer, said photo-resist layer patterned to define pockets on said deposition surface;
treating said device to raise the surface energy of said deposition surface and lower the surface energy of said photo-resist layer;
reformulating an organic solution by mixing a base organic solution with humectants; and
depositing drops of said reformulated solution into each said pocket, said drops allowed to dry into an organic layer, said organic layer having a substantially flat and uniform profile.

15. A method according to claim 14 wherein said treating includes applying a fluorinating plasma process.

16. A method according to claim 14 wherein said organic electronic device is an organic light emitting diode (OLED) display.

17. A method according to claim 16 wherein said lower electrode layer functions as an anode.

18. A method according to claim 17 wherein said organic layer is a conducting polymer layer.

19. A method according to claim 18 further comprising: fabricating an emissive layer above said conducting polymer layer, said emissive layer emitting light upon charge recombination.

20. A method according to claim 18 wherein said base organic solution is a PEDOT:PSS solution.

21. A method according to claim 20 wherein the ratio of PEDOT to PSS is one part to six parts, respectively.

22. A method according to claim 21 wherein the ratio of base organic solution to humectants to water is thirty parts to forty parts to thirty parts, respectively.

23. A method according to claim 14 wherein said device is an organic transistor.

24. A method according to claim 14 wherein said device is an organic solar cell.

25. A method according to claim 15 wherein said fluorinating plasmas process uses sulfur hexafluoride.

26. A method according to claim 14 wherein said humectants are at least one of glycols and glycol derivatives.
